(19) United States
(12) Patent Application Publication
(10) Pub. No.: US 2002/0182549 A1
(43) Pub. Date: Dec. 5, 2002

(54) Alternate exposure method for improving photolithography resolution

(76) Inventors: Ya-Hui Chang, Yenpu Hsiang (TW); Jiunn-Ren Hwang, Hsinchu City (TW)

Correspondence Address: POWELL, GOLDSTEIN, FRAZER & MURPHY LLP, P.O. BOX 97223, WASHINGTON, DC, 20090-7223, US

(21) Appl. No.: 09/870,529

(22) Filed: May 31, 2001

(51) Int. Cl. G03F 7/20

(52) U.S. Cl. 430/394; 430/322; 430/312; 430/396

(57) ABSTRACT

In accordance with the present invention, a method is provided for improving process photolithography resolution of narrow pitch patterning. The alternate exposure method for improving photolithography resolution of an original pattern with a first pitch, wherein the original pattern is a combination of a plurality of split patterns, comprises the step of providing a substrate having a layer of photoresist formed thereon. Then, a plurality of reticles having the plurality of split patterns with a second pitch is provided, wherein the second pitch is larger than the first pitch. Next, a plurality of exposures is successively performed to form a plurality of exposure regions of the plurality of split patterns in the photoresist layer using the plurality of reticles. The original pattern is transferred into the photoresist layer by combining the plurality of exposure regions of the plurality of split patterns. And then, a development of the photoresist layer is performed. Thus, the photolithography resolution of narrow pitch patterning is improved by enlarging the pitch that resulting in reducing the proximity effect and enhancing the aerial image contrast.

### BACKGROUND OF THE INVENTION

1. Field of the Invention

The present invention generally relates to a method for improving photolithography resolution, and more particularly to an alternate exposure method for improving photolithography resolution of narrow pitch patterning.

2. Description of the Prior Art

The need to remain competitive in cost and performance in the production of semiconductor devices has caused a continuous increase in device density of integrated circuits. As higher integration and miniaturization has been achieved in a semiconductor integrated circuit, miniaturization of a circuit pattern formed on a semiconductor wafer has also been proceeded. As a basic technique for generating the pattern, photolithography is widely known among others. Therefore, various development and improvements of the photolithography technique has been made.

Smaller dimensions permit the fabrication of more devices or other integrated circuit components per unit substrate area. Closer spacing of features yields similar advantages. Design rules define the space tolerance between devices or interconnect lines so as to ensure that the devices or lines do not interact with one another in any unwanted manner. One important layout design rule that tends to determine the overall size and density of the semiconductor device is the critical dimension (CD). A critical dimension of a circuit is commonly defined as the smallest width of a line or the smallest space between two lines. Another critical design rule defines the minimum width of a given feature plus the distance to the adjacent feature edge as the minimum pitch.

Once the layout of the circuit is created, the photolithographic process utilizes an exposure tool to irradiate a layer of photoresist on the wafer through a mask to transfer the pattern on the mask to the wafer. As the critical dimensions of the layout approach the resolution limit of the lithography equipment, proximity effects begin to influence the manner in which features on a mask transfer to the resist layer such that the masked and actual layout patterns begin to differ. Proximity effects are known to result from optical diffraction in the projection system. The diffraction causes adjacent features to interact with one another in such a way as to produce pattern-dependent variations; the closer together features are, the more proximity effect is seen.

One specific proximity effect related problem occurs when features are designed to have the same dimension, but are placed in a different proximity to other features in a layout. Features that have edges that are in close proximity to other features (referred to as in dense area with narrow pitch pattern) are more affected by proximity effects while features that have edges that are relatively isolated are less affected by proximity effects. As a result, a feature in a dense area tends to be printed differently than an isolated feature. That is to say, the narrow pitch pattern is difficult to print due to its poor aerial image contrast, especially for those pitches close to the wavelength of the light source used for exposure. Thus, patterns become increasingly smaller, and the need for improvement in resolution of patterns had been increased.

Generally, the term resolution is defined as a measure of the ability to separate closely spaced features. The resolution limit R (nm) in the photolithography technique using the reduction type projection printing is given by the following equation:

R=k₁*λ/(NA)

where λ is a wavelength (nm) of light for use, NA is numerical aperture of a lens, and k₁ is a constant depending on a resist process.

As can be seen from the above equation, in order to improve the resolution limit R to obtain a finer pattern, the values of k₁ and λ should be reduced, and that of NA should be increased. In other words, what is required is to reduce the constant dependent on the resist process as well as to shorten the wavelength and to increase NA. However, enlarging the numerical aperture (NA) of projection system and shortening the wavelength of light source is technically difficult and costly. The implantation of costly and complex phase shift masks has significantly improved the resolution in recent years. However, for maximizing the integration of device components in the available area on the substrate to fit more components in the same area, increasing miniaturization is required. As narrow lines and closer pitch dimensions are needed to achieve increasingly dense packing of the components, the task of reducing proximity effect and increasing the process window of printing the narrow pitch pattern with poor aerial image contrast into the substrate becomes more and more important. Thus, the need for improvement in resolution of patterning the pitches close to the wavelength of light source without considering the limitation of an image transfer system is imperative.

### SUMMARY OF THE INVENTION

The present invention is directed to an alternate exposure method for improving photolithography resolution of narrow pitch patterning. For printing narrow pitch pattern, by use of the alternate exposure method, there is no need to upgrade exposure tools, utilize advanced masks, or modify resist systems to get better aerial image contrast than using the old single exposure method under the same exposure condition. Moreover, the manufacture of masks with wider space and pitch used in the alternate exposure method is easier than that of those masks used in the conventional single exposure method.

It is another object of this invention that an alternate exposure method for improving photolithography resolution with easily made masks is provided.

It is a further object of this invention that an alternate exposure method for improving the aerial image contrast of narrow pitch patterning by utilizing a plurality of reticles having wider pitch patterns is provided.

In accordance with the present invention, in one embodiment, an alternate exposure method for improving photolithography resolution of narrow pitch patterning is disclosed. The alternate exposure method for improving photolithography resolution of an original pattern with a first pitch, wherein the original pattern is a combination of a plurality of split patterns, comprises the step of providing a substrate having a layer of photoresist formed thereon. Then, a plurality of reticles having the plurality of split patterns with a second pitch is provided, wherein the second pitch is larger than the first pitch. Next, a plurality of exposures is successively performed to form a plurality of exposure regions of the plurality of split patterns in the photoresist layer using the plurality of reticles. The original pattern is transferred into the photoresist layer by combining the plurality of exposure regions of the plurality of split patterns. And then, a development of the photoresist layer is performed. Thus, the photolithography resolution of narrow pitch patterning is improved by enlarging the pitch that resulting in reducing the proximity effect and enhancing the aerial image contrast. The method of forming the photoresist layer comprises steps of coating a layer of photoresist on the substrate and soft-baking the photoresist layer. The step of successively performing said plurality of exposures comprises that one of the reticles having one of the split patterns is aligned above with the substrate. Then, one of the exposures is performed to form one of the exposure regions of the split patterns in the photoresist layer. And then, steps of aligning and performing are repeated by changing the reticles till the original pattern is transferred into the photoresist layer. The method further comprises a step of post exposure baking the photoresist layer prior to performing the development. The method further comprises one of steps of doping, etching, and forming layers to produce an integrated circuit.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a flow diagram showing the steps for improving photolithography resolution of narrow pitch patterning in accordance with the present invention;

FIGS. 2A and 2B are a schematic cross-sectional view of exposing a desired narrow pitch pattern and its aerial image simulation diagram of the conventional single exposure method;

FIGS. 3A to 3C is schematic cross-sectional view of exposing the desired narrow pitch pattern by use of the alternate exposure method in one embodiment;

FIGS. 4A to 4C is an aerial image simulation diagram of the desired narrow pitch pattern exposed by use of the alternate exposure method in one embodiment; and

FIGS. 5A and 5B are schematic aerial image simulation diagrams of comparing with the conventional single exposure method and the alternate exposure method of double and triple exposures by using binary mask and phase shift mask, respectively.

### DESCRIPTION OF THE PREFERRED EMBODIMENT

Some sample embodiments of the invention will now be described in greater detail. Nevertheless, it should be noted that the present invention can be practiced in a wide range of other embodiments besides those explicitly described, and the scope of the present invention is expressly not limited except as specified in the accompanying claims.

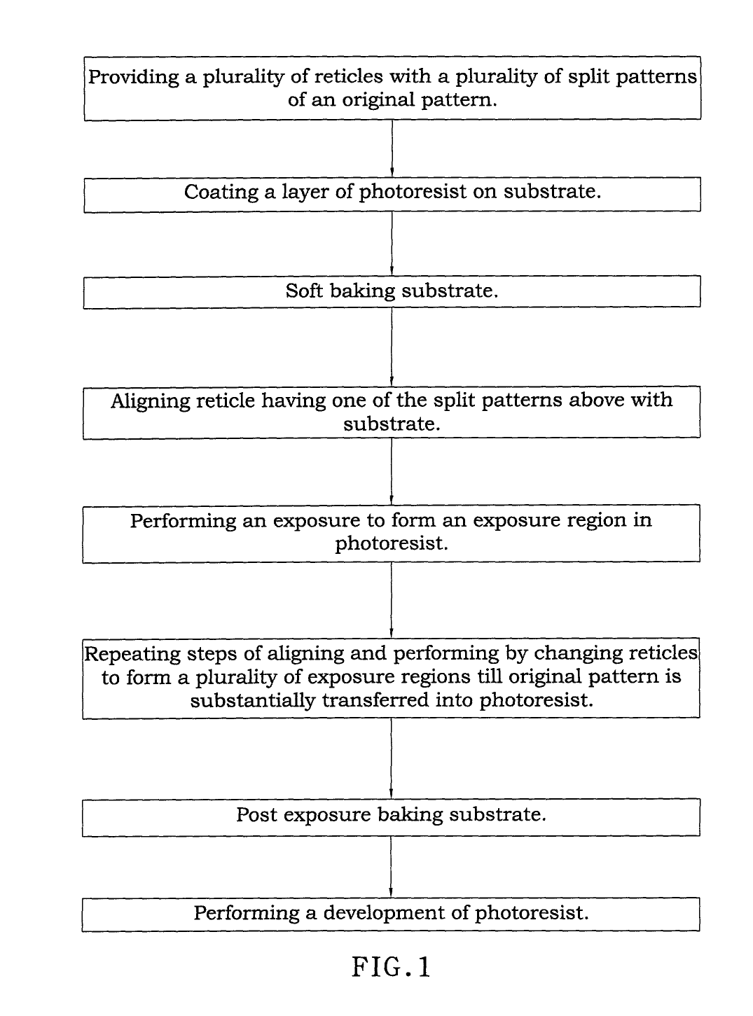

In one embodiment, the alternate exposure method for improving photolithography resolution of an original pattern is disclosed. The original pattern having a first pitch is a combination of a plurality of split patterns. A plurality of reticles having the plurality of split patterns with a second pitch is provided, wherein the second pitch is larger than the first pitch. FIG. 1 is a flow diagram summarizing the steps in an alternate exposure method of improving the photolithography resolution of narrow pitch patterning in accordance with the present invention. First, a layer of photoresist is coated on a provided substrate. The alternate exposure method can be performed with a negative or a positive photoresist. Next, the photoresist layer is soft-baked to enhance the adhesion of photoresist to the substrate. Then, a plurality of exposures is successively performed to form a plurality of exposure regions of the plurality of split patterns in the photoresist layer using the plurality of reticles. Next, a post exposure baking of the photoresist layer is performed. Then, a development of the photoresist layer is performed. Thus, the photolithography resolution of narrow pitch patterning is improved by enlarging the pitch that results in reducing the proximity effect and enhancing the aerial image contrast.

It is noted that how many times of performing the exposure step and changing the reticles is determined by the number of reticles provided, and till the original pattern is transferred into the photoresist layer by combining the plurality of exposure regions of the plurality of split patterns. The step of successively performing said plurality of exposures comprises that one of the reticles having one of the split patterns is aligned above with the substrate. Next, one of the exposures is performed to form one of the exposure regions of the split patterns in the photoresist layer. And then, steps of aligning and performing are repeated by changing the reticles till the original pattern is substantially transferred into the photoresist layer. The method further comprises one of steps of doping, etching, and forming layers to produce an integrated circuit.

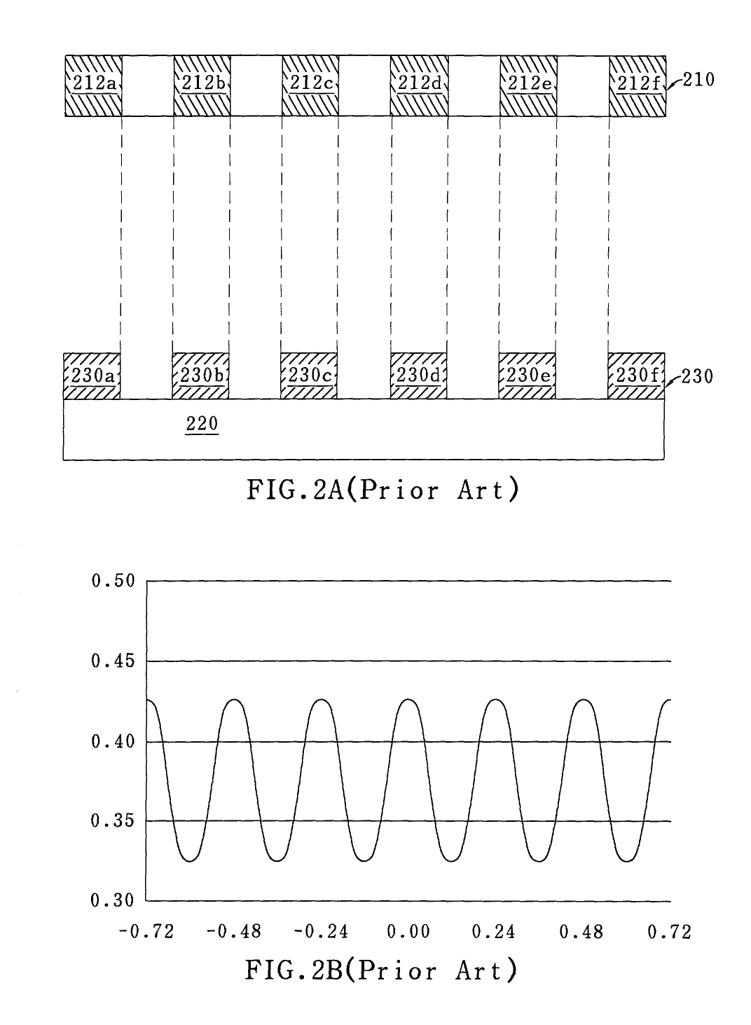

Referring to FIGS. 2A and 2B, a cross-sectional view of exposing a desired narrow pitch pattern and its aerial image simulation diagram by use of the conventional single exposure method is shown, respectively. It shows that a reticle 210 having an original pattern with six closely spaced features is transferred into a layer of photoresist 230 formed on a substrate 220. The original pattern on the reticle 210, which is those portions of the reticle coated with chrome, is indicated by reference numerals 212a, 212b, 212c, 212d, 212e, and 212f. By use of the conventional single exposure method, the original pattern is transferred into the photoresist layer 230 to form six feature regions of 230a, 230b, 230c, 230d, 230e, and 230f. The pitch is defined as the width of a given feature plus the distance to the adjacent feature edge. The space between two adjacent features is indicated as S nanometer (nm), and the pitch is indicated as P nm. Thus, the feature width is (P-S) nm. The value of S and P is 120 and 240 nm, respectively.

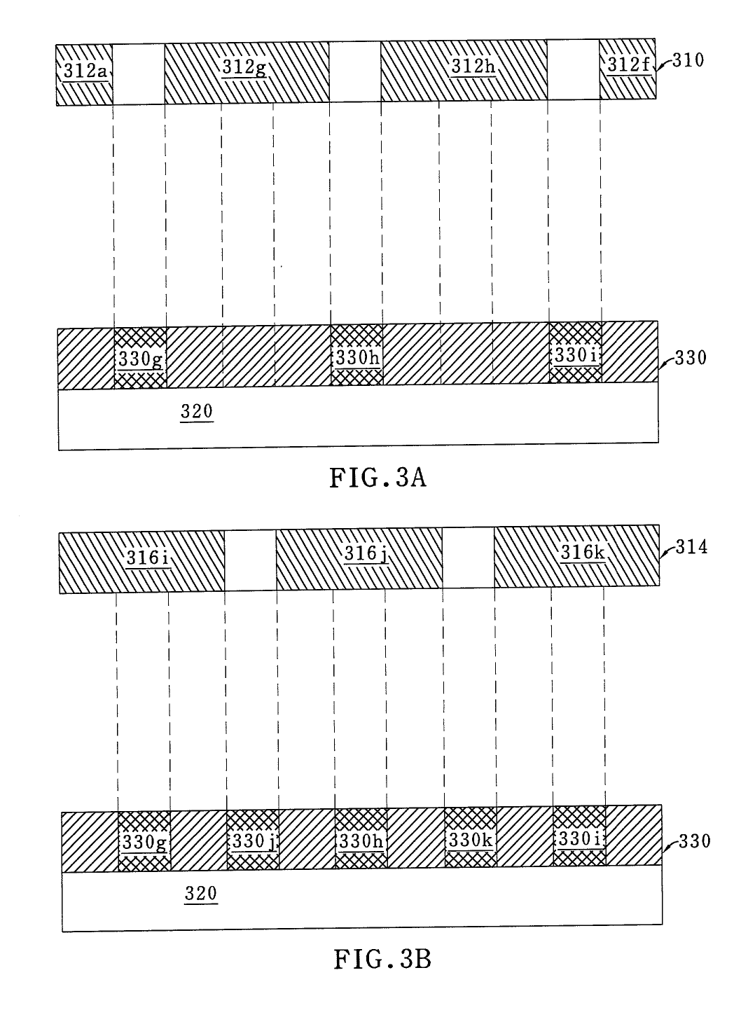

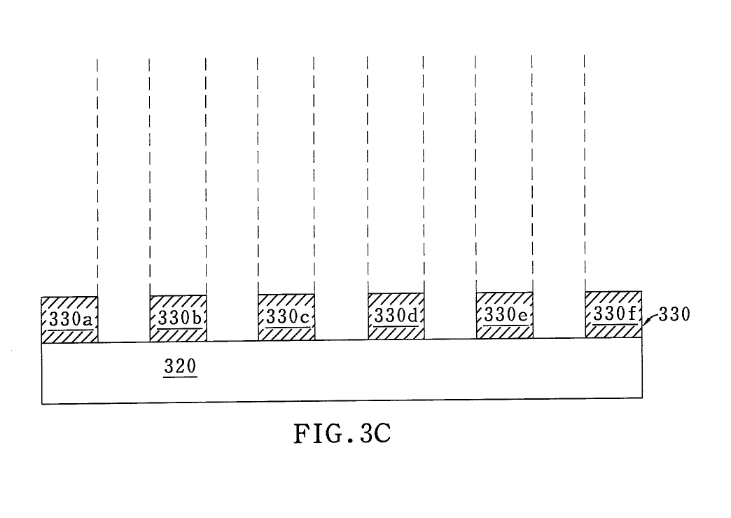

FIGS. 3A to 3C illustrates an alternate exposure method using two reticles with wider pitch to create a closely spaced pattern with improved resolution. For patterning an original pattern with a first pitch and a first space, such as P nm and S nm, the alternate exposure method can be made by exposing with masks having split patterns with P multiplying n′ nm pitch and S nm space n times alternately. The n′ is a real number at least equal 2 and n is an integer at least equal to 2 (n′≧2, n≧2). In one embodiment, for patterning an original pattern with a pitch of 240 nm and space 120 nm shown in FIG. 2A, the alternate exposure method comprises the step of providing a substrate 320 having a layer of photoresist 330 formed thereon. The alternate exposure method can be performed with a negative or a positive photoresist. Next, the substrate is soft-baked to enhance the adhesion of photoresist to the substrate.

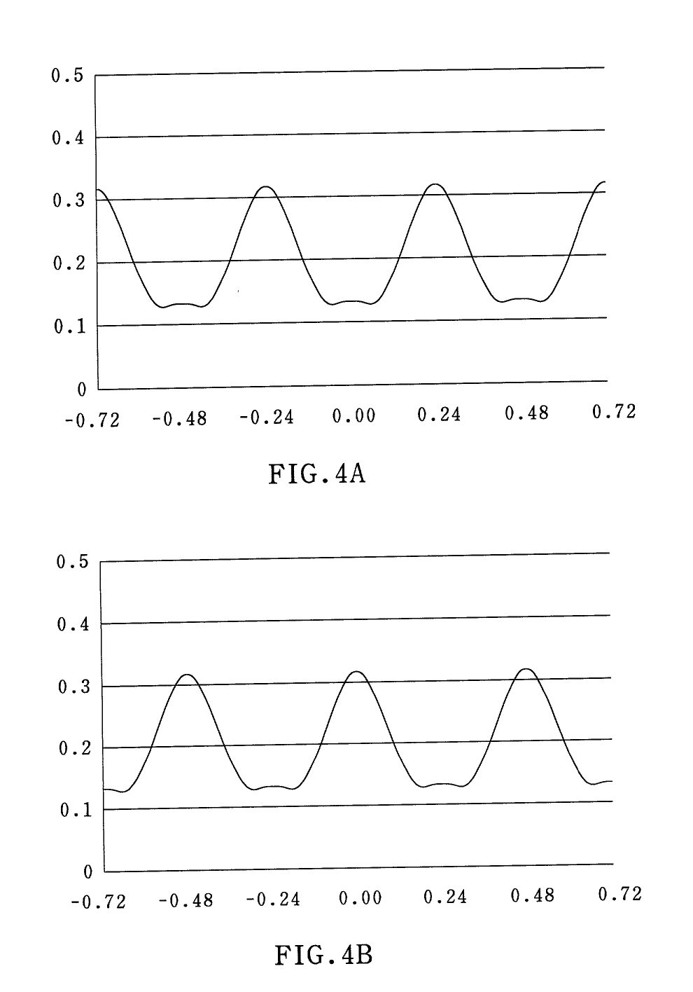

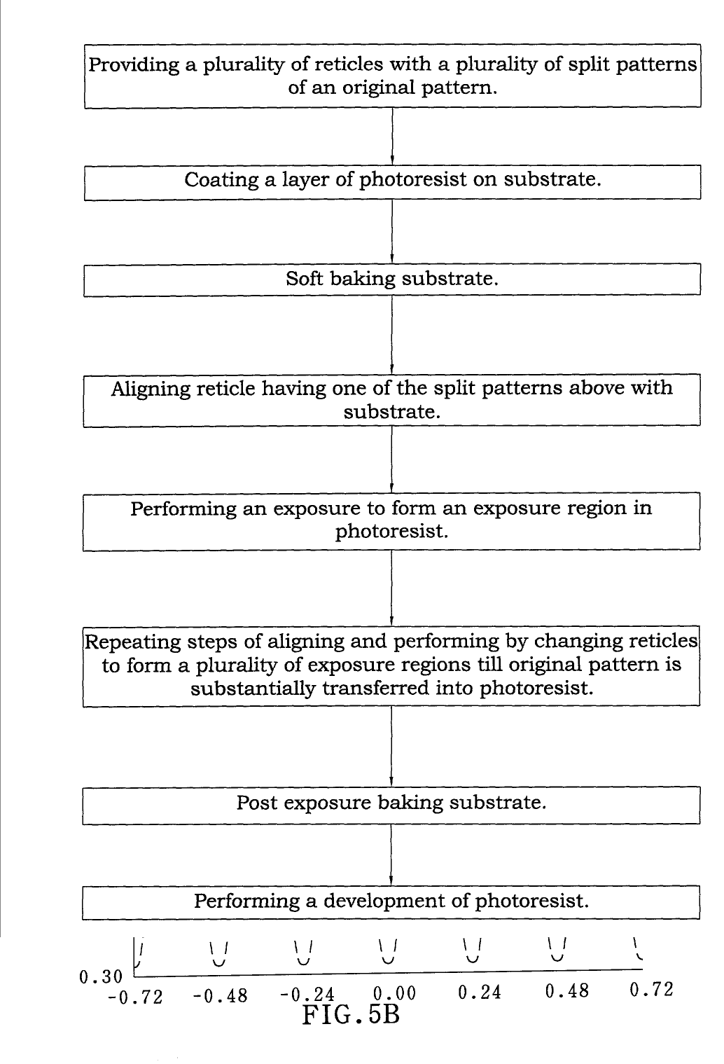

For the alternate exposure method of double exposure in a positive phtoresist (n is 2), two reticles having split patterns with a second pitch are provided. The original pattern is a combination of the purality of split patterns. The second pitch is larger than the first pitch, the value of n′ is 2. That is to say, the reticles having a 480 nm pitch and 120 nm space are provided. Next, a first reticle 310 is aligned above with the substrate 320. The first split pattern on the reticle 310, which is those portions of the reticle coated with chrome, is indicated by reference numerals 312a, 312g, 312h, and 312f. The space in the first split pattern is kept 120 nm but pitch including 312g or 312h has been enlarged to 480 nm. Performing a first exposure, the first split pattern is transferred into the photoresist layer 330 to form three exposure regions of 330g, 330h, and 330i in the photoresist layer 330, as shown in FIG. 3A. The aerial image contrast of the first exposure is shown in FIG. 4A.

Then, changing a second reticle 314 is aligned above with the substrate 320. The second split pattern on the reticle 314, which is those portions of the reticle coated with chrome, is indicated by reference numerals 316i, 316j, and 316k. The space in the second split pattern is kept 120 nm but pitch including 316i, 316j, or 316k has been enlarged to 480 nm. Performing a second exposure, the second split pattern is transferred into the photoresist layer 330 to form two exposure regions of 330j and 330k in the photoresist layer 330, as shown in FIG. 3B. The aerial image contrast of the second exposure is shown in FIG. 4B. The step of post exposure can be performed after the successively exposing procedures. Next, a development of the photoresist layer is performed. The regions 330g, 330h, 330i, 330j and 330k of the photoresist layer are removed, the combination of portions of the photoresist left, 330a, 330b, 330c, 330d, 330e, and 330f is the original pattern transferred into the photoresist layer with 240 nm pitch and 120 nm space, as shown in FIG. 3C. The final image print on the substrate is equal to the first aerial image contrast plus the second aerial image contrast, as shown in 4C, which is improved by the alternate exposure method comparing to that of conventional method shown in FIG. 2B. The method further comprises one of steps of doping, etching, and forming layers to produce an integrated circuit.

Referring to 5A and 5B, schematic aerial image simulation diagram of comparing with the conventional single exposure method and the alternate exposure method of double and triple exposures by using binary mask and phase shift mask (6% half tone) is provided, respectively. The application and technique of manufacturing the reticles is of no importance. It is clear that the more alternate exposure is made, the aerial image contrast is better improved, in other words, the broader the pitch on the reticle gets the better aerial image contrast and the easier the reticle is to make. The aerial image contrast of triple exposures is better than that of double exposures, and that of double is better than that of single exposure.

Although specific embodiments have been illustrated and described, it will be obvious to those skilled in the art that various modifications may be made without departing from what is intended to be limited solely by the appended claims.

What is claimed is:

1. An alternate exposure method for improving photolithography resolution of an original pattern with a first pitch, wherein said original pattern is a combination of a plurality of split patterns, said method comprising:
providing a substrate having a layer of photoresist formed thereon;
providing a plurality of reticles having said plurality of split patterns with a second pitch, wherein said second pitch is larger than said first pitch;
successively performing a plurality of exposures to form a plurality of exposure regions of said plurality of split patterns in said photoresist layer using said plurality of reticles, wherein said original pattern is transferred into said photoresist layer by combining said plurality of exposure regions of said plurality of split patterns; and
performing a development of said photoresist layer.

2. The method according to claim 1, wherein method of forming said photoresist layer comprises:
coating said photoresist layer on said substrate; and
soft-baking said photoresist layer.

3. The method according to claim 1, wherein said step of successively performing said plurality of exposures comprises:
aligning one of said reticles having one of said split patterns above with said substrate;
performing one of said exposures to form one of said exposure regions of said split patterns in said photoresist layer; and
repeating said steps of aligning and performing by changing said reticles till said original pattern is transferred into said photoresist layer.

4. The method according to claim 1, further comprising a step of post exposure baking said photoresist layer prior to performing said development.

5. The method according to claim 1, further comprising steps for doping, etching, and forming layers to produce an integrated circuit.

6. The method according to claim 1, wherein at least two said reticles are provided.

7. The method according to claim 1, wherein at least three said reticles are provided.

8. An alternate exposure method for improving photolithography resolution of an original pattern with a first pitch, wherein said original pattern is a combination of a plurality of split of patterns, said method comprising:
providing a substrate having a layer of photoresist formed thereon;
providing a plurality of reticles having said plurality of split patterns with a second pitch, wherein said second pitch is larger than said first pitch;
aligning one of said reticles having one of said split patterns above with said substrate;
performing an exposure to form an exposure region of said one of said split patterns in said photoresist layer;
repeating said steps of aligning and performing by changing said reticles to form a plurality of said exposure regions in said photoresist layer, wherein said original pattern is transferred into said photoresist layer by combining said plurality of exposure regions of said plurality of split patterns; and
performing a development of said photoresist layer.

9. The method according to claim 8, wherein method of forming said photoresist layer comprises:
coating said photoresist layer on said substrate; and
soft-baking said photoresist layer.

10. The method according to claim 8, further comprising a step of post exposure baking said photoresist layer prior to performing said development.

11. The method according to claim 8, further comprising one of steps of doping, etching, and forming layers to produce an integrated circuit.

12. The method according to claim 8, wherein at least two said reticles are provided.

13. The method according to claim 8, wherein at least three said reticles are provided.

14. An alternate exposure method for improving photolithography resolution of an original pattern with a first pitch, wherein said original pattern is a combination of a first and a second split patterns, said method comprising:
providing a substrate having a layer of photoresist formed thereon;
providing a first reticle having said first split pattern with a second pitch larger than said first pitch;
performing a first exposure to form a first exposure region of said first split pattern into said photoresist layer using said first reticle;
providing a second reticle having said second split pattern with a third pitch larger than said first pitch;
performing a second exposure to form a second exposure region of said second split pattern into said photoresist layer using said second reticle, wherein said original pattern is transferred into said photoresist layer by combining said first and said second exposure regions of said first and said second split patterns; and
performing a development of said photoresist layer.

15. The method according to claim 14, wherein method of forming said photoresist layer comprises:
coating said photoresist layer on said substrate; and
soft-baking said photoresist layer.

16. The method according to claim 14, wherein said step of performing said fist exposure comprises:
aligning said first reticles having said first split pattern above with said substrate; and
performing said first exposure to form said first exposure region of said first split pattern in said photoresist layer.

17. The method according to claim 14, wherein said step of performing said second exposure comprises:
aligning said second reticle having said second split pattern above with said substrate; and
performing said second exposure to form said second exposure region of said second split pattern in said photoresist layer.

18. The method according to claim 14, further comprising a step of post exposure baking said photoresist layer prior to performing said development.

19. The method according to claim 14, further comprising one of steps of doping, etching, and forming layers to produce an integrated circuit.
